(19) United States
(12) Patent Application Publication
(10) Pub. No.: US 2025/0275216 A1
(43) Pub. Date: Aug. 28, 2025

(54) GaN DEVICE WITH HOLE ELIMINATION CENTERS

(71) Applicant: Efficient Power Conversion Corporation, El Segundo, CA (US)

(72) Inventors: Robert Strittmatter, Tujunga, CA (US); Jianjun Cao, Torrance, CA (US); Robert Beach, La Crescenta, CA (US); Muskan Sharma, Lakewood, CA (US); Wen-Chia Liao, Torrance, CA (US); Alexander Lidow, Topanga, CA (US); Massimo Grasso, Trivolzio (PV) (IT); Sergio Morini, Pavia (IT)

(73) Assignee: Efficient Power Conversion Corporation, El Segundo, CA (US)

(21) Appl. No.: 19/207,772

(22) Filed: May 14, 2025

Related U.S. Application Data
(63) Continuation-in-part of application No. 18/436,352, filed on Feb. 8, 2024.
(60) Provisional application No. 63/483,997, filed on Feb. 9, 2023.
(60) Provisional application No. 63/504,084, filed on May 24, 2023.

(51) Int. Cl. H10D 64/27; H10D 30/01; H10D 30/47; H10D 62/85

(52) U.S. Cl. CPC H10D 64/411; H10D 30/015; H10D 30/475; H10D 62/8503

(57) ABSTRACT

An enhancement mode gallium nitride (GaN) transistor configured to eliminate holes in the gate material under the gate metal. The transistor has four electrodes, namely a drain electrode, a source electrode, a gate electrode and a hole collector electrode. In a preferred embodiment, a negative voltage is applied to the hole collector electrode, attracting holes in the gate material under the gate metal. The attracted holes recombine with electrons supplied by the negative voltage, thereby substantially eliminating the holes.

### CROSS-REFERENCE TO RELATED APPLICATIONS

This application is a continuation-in-part of U.S. application Ser. No. 18/436,352, filed Feb. 8, 2024, which claims the benefit of U.S. Provisional Application Nos. 63/483,997, filed Feb. 9, 2023, and U.S. Provisional Application No. 63/504,084, filed May 24, 2023, the disclosures of which are incorporated by reference herein in their entireties.

### BACKGROUND OF THE INVENTION

### 1. Field of the Invention

The present invention relates to the field of column III nitride transistors such as gallium nitride (GaN) transistors.

### 2. Description of the Related Art

Gallium nitride (GaN) semiconductor devices are increasingly desirable for power semiconductor devices because of their ability to carry large current and support high voltages. Development of these devices has generally been aimed at high power/high frequency applications. Devices fabricated for these types of applications are based on general device structures that exhibit high electron mobility and are referred to variously as heterojunction field effect transistors (HFET), high electron mobility transistors (HEMT), or modulation doped field effect transistors (MODFET).

A GaN HEMT device includes a nitride semiconductor with at least two nitride layers. Different materials formed on the semiconductor or on a buffer layer cause the layers to have different band gaps. The different material in the adjacent nitride layers also causes polarization, which contributes to a conductive two-dimensional electron gas (2DEG) region near the junction of the two layers, specifically in the layer with the narrower band gap.

The nitride layers that cause polarization typically include a barrier layer of AlGaN adjacent to a layer of GaN to include the 2DEG, which allows charge to flow through the device. This barrier layer may be doped or undoped. Because the 2DEG region exists under the gate at zero gate bias, nitride devices are inherently normally on, or depletion mode devices. If the 2DEG region is depleted, i.e. removed, below the gate at zero applied gate bias, the device is an enhancement mode device. Enhancement mode devices are normally off and are desirable because of the added safety they provide and because they are easier to control with simple, low-cost drive circuits. An enhancement mode device requires a positive bias applied at the gate in order to conduct current.

FIG. 1 illustrates an enhancement mode GaN transistor disclosed in U.S. Pat. No. 8,890,168, the entire disclosure of which is incorporated herein by reference. The GaN device of FIG. 1 includes a silicon substrate 11, transition layers 12, undoped GaN buffer material 13, undoped AlGaN barrier layer 14, p-type GaN gate material 15, gate metal 17, dielectric material 18, drain ohmic contact 19, and source ohmic contact 20.

Referring to FIG. 2, like all enhancement mode GaN transistors, the GaN device of FIG. 1 conducts current from drain 19 to source 20 when the drain is biased positive with respect to the source, and a positive voltage is applied to the gate 30. However, as indicated in FIG. 1, under a high voltage drain bias, holes generated in the drain region (or other regions of the device where high electric fields exist) drift toward the gate and become trapped or confined within the p-type GaN gate layer. The arrow “a” illustrates holes above the front barrier moving toward the gate material, arrow “b” illustrate holes under the front barrier which partially move toward the gate material directly below the gate, and arrow “c” shows holes under the front barrier which move toward the source. Under gate bias, hole generation may also occur in the gate region itself. The accumulation of these holes in the gate material under the gate metal, over time, disadvantageously causes lower threshold voltage and higher drain-to-source leakage current when the device is off.

FIGS. 3A, 3B are reproduced from Giorgino et al., “Study of Magnesium Activation Effect on Pinch-Off Voltage of Normally-Off p-GaN HEMTs for Power Applications,” Crystals 2023, Vol. 13, No. 3, 1309. Giorgino discloses and compares: (1) a single-RTP process, characterized by Mg doping during the epitaxial growth of the GaN cap and a standard Rapid Thermal Processing (RTP) for Mg activation (temperature in the range of 700-850° C. for a time duration of 1-10 min), performed after the p-GaN growth; and (2) a multiple-RTP process, featuring Mg doping during the epitaxial growth of the GaN cap, but with improved Mg activation by performing the RTP activation process several times during the device process flow. As shown in FIG. 3A, the multiple RTA process results in the p-GaN gate material having two regions, a depleted region of p-GaN that has no mobile holes, and an undepleted region of p-GaN that has mobile holes (the single RTP process has a depleted region only, and no undepleted region). The presence of mobile holes in the p-GaN leads to higher gate capacitance, as shown in FIG. 3B. Giorginio et al. recognize additional drawbacks to having mobile holes in the p-GaN gate material, namely higher gate leakage; higher hysteresis and VTH instability; and increased current collapse in dynamic conditions.

For all of the above-noted reasons, it would be desirable to provide an enhancement mode GaN transistor in which holes in the GaN gate material are removed.

### SUMMARY OF THE INVENTION

The present invention advantageously provides an enhancement mode GaN transistor with

a feature that attracts holes in the GaN gate material under the gate metal, and continuously removes them from the gate material. The holes are removed from the gate material by any of several transport processes, including but not limited to: (1) recombination of the holes with electrons, thereby neutralizing the holes; (2) thermionic emission of holes over a Schottky metal contact, preferably with the contact biased at a negative voltage to enhance emission; and (3) tunneling or injection of holes across an ohmic contact. Using any of the above, holes are removed from the gate material, such that the device is capable of withstanding higher voltage.

The GaN gate material has two overlaying electrodes: a gate electrode and a hole collector electrode. The hole collector electrode may make either a Schottky or an ohmic contact to the underlying GaN gate material. The hole collector electrode is disposed at the top surface of the GaN gate material and/or can extend into or through the GaN gate material. The GaN gate material between the hole collector electrode and the gate electrode may be thinner than the GaN gate material under the gate electrode.

In accordance with the invention, a negative voltage is applied to the hole collector electrode, such that holes under the gate are attracted and recombine with electrons supplied by the negative voltage connected to the hole collector electrode, thereby substantially eliminating the holes in the GaN gate material.

The negative voltage supplied to the hole collector electrode can be generated by a negative voltage generating circuit implemented in GaN and integrated with the enhancement mode GaN transistor. In some embodiments, the negative voltage supplied to the hole collector electrode can be generated by a silicon IC co-packaged with the GaN device of this invention. In other embodiments, the negative voltage supplied to the hole collector electrode can be supplied externally by the user.

### BRIEF DESCRIPTION OF THE DRAWINGS

The features, objects, and advantages of the present invention will become more apparent from the detailed description set forth below when taken in conjunction with the drawings in which like reference characters identify correspondingly throughout and wherein:

FIG. 1 illustrates a cross-sectional view of a prior art enhancement mode GaN transistor.

FIG. 2 is a top view of the prior art GaN device of FIG. 1.

FIGS. 3A, 3B illustrate the effect of mobile holes in the gate material.

FIG. 4A shows a top view of a first embodiment of the GaN device of the present invention.

FIG. 4B shows a cross-section side view of another embodiment.

FIG. 5A show a cross-section taken along line A-A of FIG. 5B.

FIG. 5B shows a closer top view of the first embodiment, FIG. 4A, of the present invention.

FIG. 5C is a cross-section taken along lines B-B of FIG. 5B.

FIGS. 6A, 6B show an alternative layout in which the gate line forms a racetrack surrounding the drain contact.

FIGS. 7A-7D show various possible connections of the hole collector metal to the GAN gate material.

FIG. 8 shows a depletion mode GaN FET configured as a linear supply in the negative voltage generating circuit of the present invention.

FIG. 9 shows a depletion mode GaN FET in the sensor circuitry of the voltage generating circuit.

FIG. 10 is a circuit schematic of the charge pump circuitry of the negative voltage generating circuit.

FIG. 11 is a circuit schematic of the entire negative voltage generating circuit.

FIG. 12A is another embodiment illustrating a connection of the hole collector metal to the GaN material.

FIG. 12B is another embodiment illustrating a thinned region of the GaN material.

FIGS. 13A, 13B(1), 13B(2), 13C, 13D, 13E, 13F, 13G illustrate a process of fabricating a GaN device in accordance with embodiments herein.

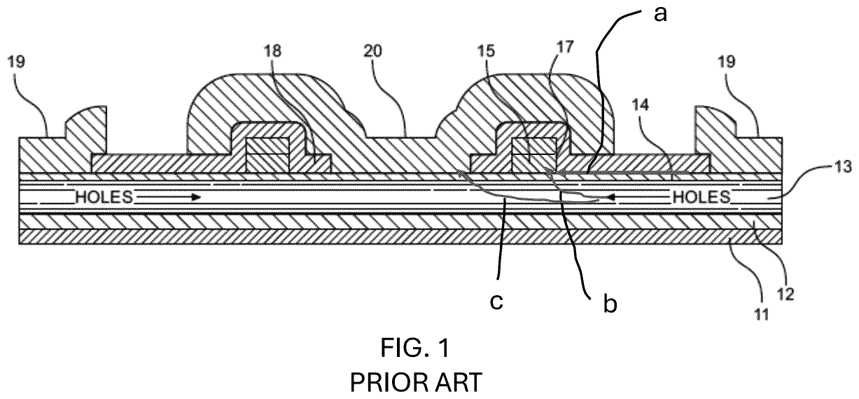

### DETAILED DESCRIPTION OF THE PREFERRED EMBODIMENTS

In the following detailed description, reference is made to certain embodiments. This detailed description is merely intended to teach a person of skill in the art further details for practicing preferred aspects of the present teachings and is not intended to limit the scope of the claims. Therefore, combinations of features disclosed in the following detailed description may not be necessary to practice the teachings in the broadest sense, and are instead taught merely to describe particularly representative examples of the present teachings. It is to be understood that other embodiments may be employed and that various structural, logical, and electrical changes may be made.

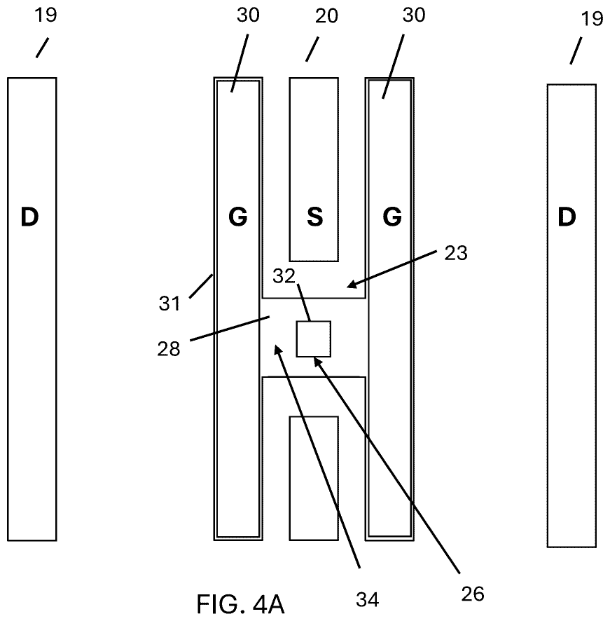

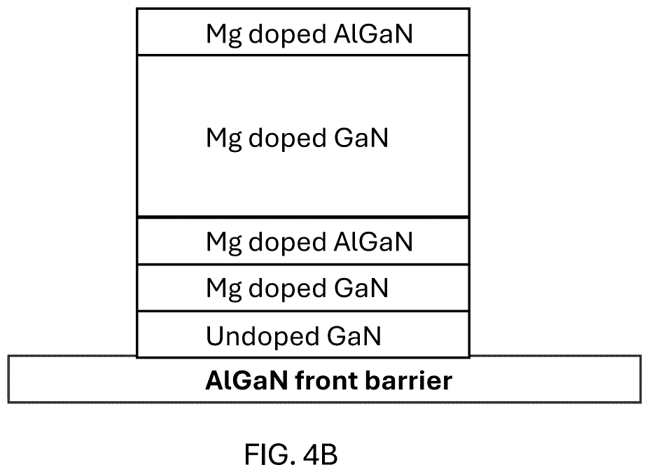

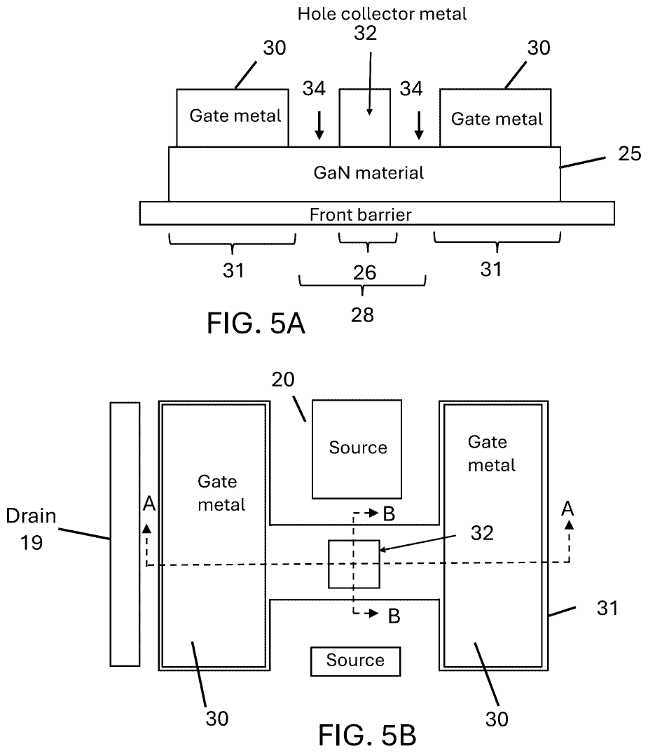

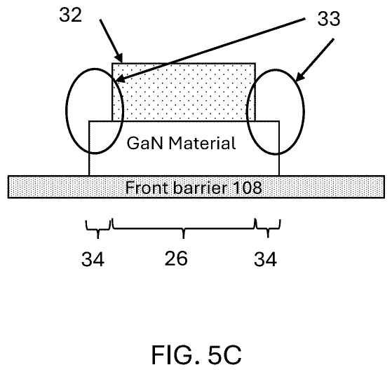

FIGS. 4A, 5B show top views of a first embodiment of the device of the present invention, FIG. 5A shows a cross-section view taken along line A-A of FIG. 5B, and FIG. 5C shows a cross-section view taken along line B-B of FIG. 5B. The device includes a source 20, gate 30, drain 19, a hole collector assembly 23, and a III-V material layer, here a GaN material layer 25. The gate metal 30 is laterally disposed between the ohmic contacts 19, 20 for the drain (D) and source (S), respectively. The gate metal 30 is formed over the GaN layer 25. As best seen in FIG. 5A, the hole collector assembly 23 includes a hole collector metal 32, which is also formed over the GaN layer 25 and is disposed between two portion of the gate metal 30.

As shown in FIGS. 4A, 5A, 5B, 5C, the GaN layer 25 is a continuous material formed over the front barrier layer, and includes a gate material section 31 under the gate metal 30 and a bridge section 28 between the gate metals 30. The bridge section 28 includes a hole collector section 26 of the GaN material 25 which is directly below the hole collector metal 32, and an uncovered section 34 section not directly below the hole collector metal 32, but to the sides of the hole collector metal 32. The bridge section 28 of the hole collector GaN material 25 extends between the gates 30, and couples the hole collector metal 32 to the gate material section 31.

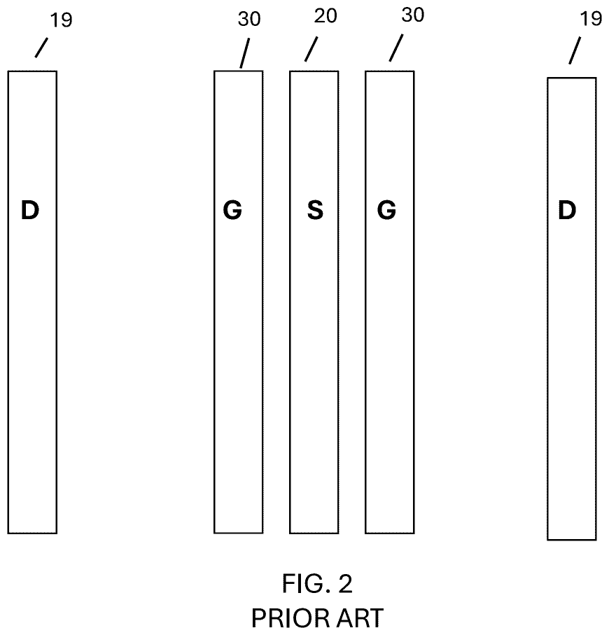

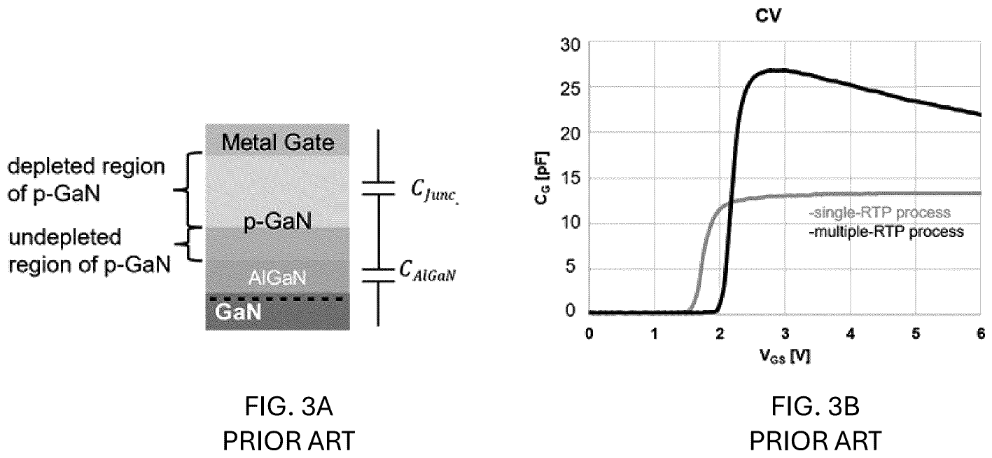

The gate metal 30 is disposed over the GaN gate section 31, which is slightly larger than the gate metal 30, to form ledges 33 (FIG. 5C) of the GaN gate material. It is noted that gate ledges need not be provided, such that the gate metal 30 can be the same size as the underlying GaN gate material; in such a case, the periphery of the GaN gate material section 31 is not visible in a top view, as shown for example in FIGS. 2, 6 and 7.

The hole collector metal 32 is formed over at least a part of the GaN hole collector section 28. The hole collector eliminates holes that either pre-exist or accumulate in the GaN gate material under the gate metal 30. In the preferred embodiment of the present invention, the holes are removed from the gate region by any of several transport processes, including but not limited to: (1) recombination of the holes with electrons, thereby neutralizing the holes; (2) thermionic emission of holes over a Schottky metal contact; and (3) tunneling or injection of holes. As disclosed in more detail below, the electrons are sourced from a negative voltage generating circuit and injected into the GaN gate material of the enhancement mode GaN device.

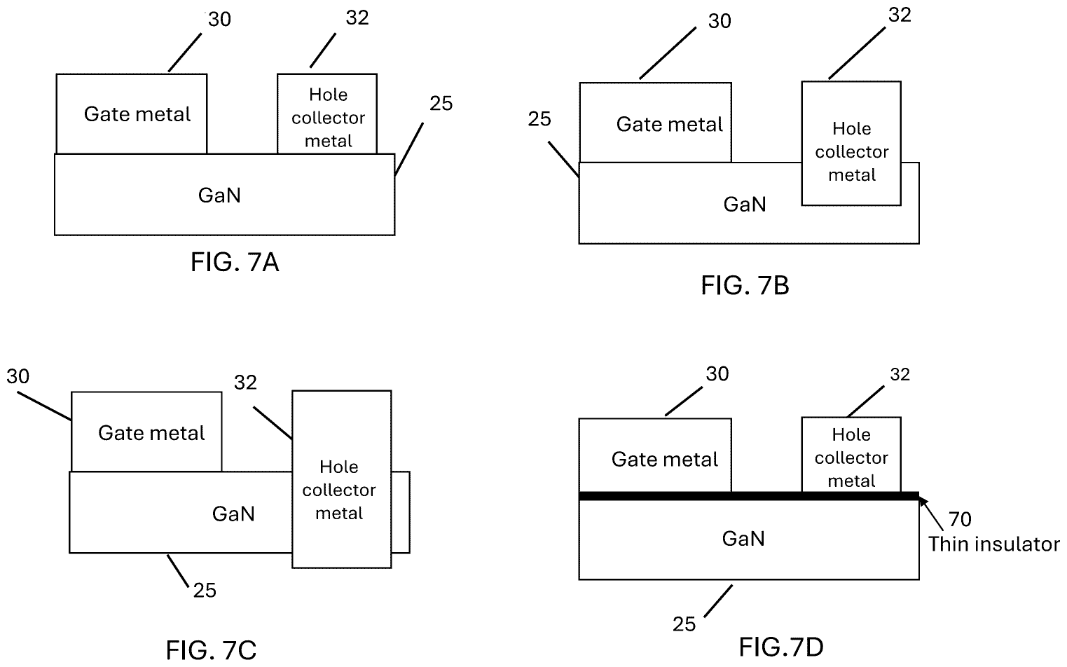

Thus, as best shown in the central portion of the top view of FIGS. 4A, 5A, 5C, the GaN material 25 is formed of three sections: (1) a section 31 in which the gate metal 30 is disposed over the GaN material 25 of the gate lines; (2) a section 26 in which the hole collector electrode 32 contacts the GaN material, as disclosed in further detail below with respect to FIGS. 7A-7D; and (3) an uncovered section 34, in which the GaN material has no metal over it, i.e., a distance exists between the gate metal 30 and the hole collector metal 32.

The GaN layer 25 is preferably composed of AlₓGa_{y}In_{(1-x-y)}N of varying x and y values. The GaN material 25 is preferably doped with a p-type dopant such as magnesium to create an enhancement mode device. The p-type GaN can be compensated, as disclosed in U.S. Pat. No. 8,350,294, the disclosure of which is incorporated herein by reference.

As shown in the example embodiment of FIG. 4B, the GaN layer 25 can have an undoped GaN bottom layer that is formed on the front barrier. A Mg doped layer of GaN can then be formed over the undoped GaN layer, followed by a Mg doped AlGaN layer, a Mg doped GaN layer, and a Mg doped AlGaN top layer. The thickness of the entire GaN material is from 20 nm to 120 nm.

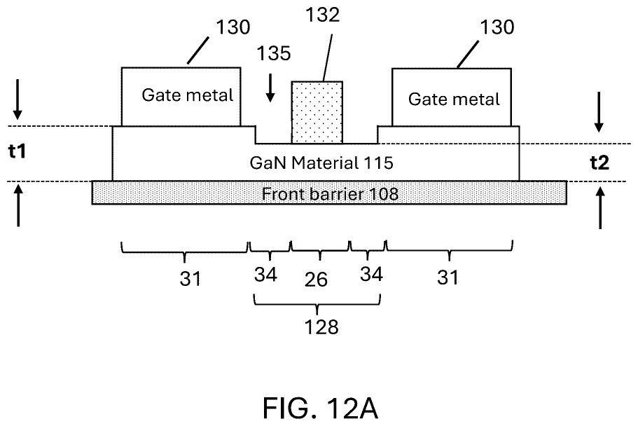

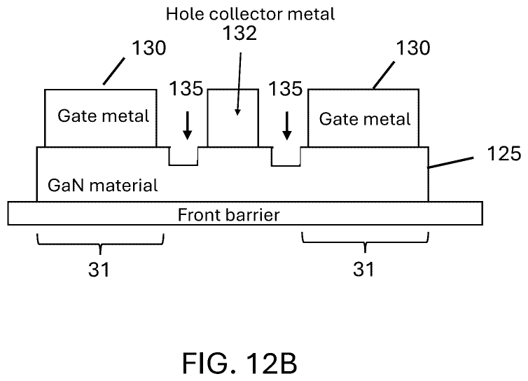

The GaN material below the hole collector contact metal 32 (FIGS. 4-7), 132 (FIGS. 12A-12B) may be thinner than the GaN material of the gate lines 30, 130. Likewise, the hole collector section 28, 128 of the GaN material 25 can either have the same thickness as the GaN material of the gate lines 30, 130, or can be thinner than the gate lines. FIGS. 12A and 12B illustrate the case where the GaN material is thinner, at least in part, in the gap between the gate contact metal and the hole collector metal. In FIG. 12A, the entire bridge section 128 (including the hole collector section 26 and the uncovered section 34) is thinner than the gate section 31; whereas in FIG. 12B, the uncovered section 135 is thinner, and the hole collector section 34 is the same thickness as the gate section 31.

A cross-sectional view of the first embodiment of the present invention is shown in FIG. 5A. The gate metal 30 is preferably TiN. The hole collector metal 32 may be formed of the same metal as the gate metal 30, or may be formed of a different metal. The contact of the hole collector metal 32 to the GaN material 25 preferably has a lower barrier height than the gate metal contact to the GaN material 25, and serves as a preferential site to attract holes and, in the preferred embodiment, neutralize the holes with electrons.

FIG. 5C shows a cross-section view taken along line B-B of FIG. 5B. The GaN material 25 may be 20 nm to 120 nm thick. The gate metal 30, 130 and the hole collector metal 32, 132 (FIGS. 5A, 5B) are spaced apart by a distance of about 0.1 μm to 50 μm. In the embodiment of FIGS. 5A-5C, the GaN material layer 25 has a uniform thickness. FIG. 5C illustrates self-aligned gate ledges 33 to space the hole collector metal 32 from a side surface of the GaN uncovered material 34 to reduce gate leakage.

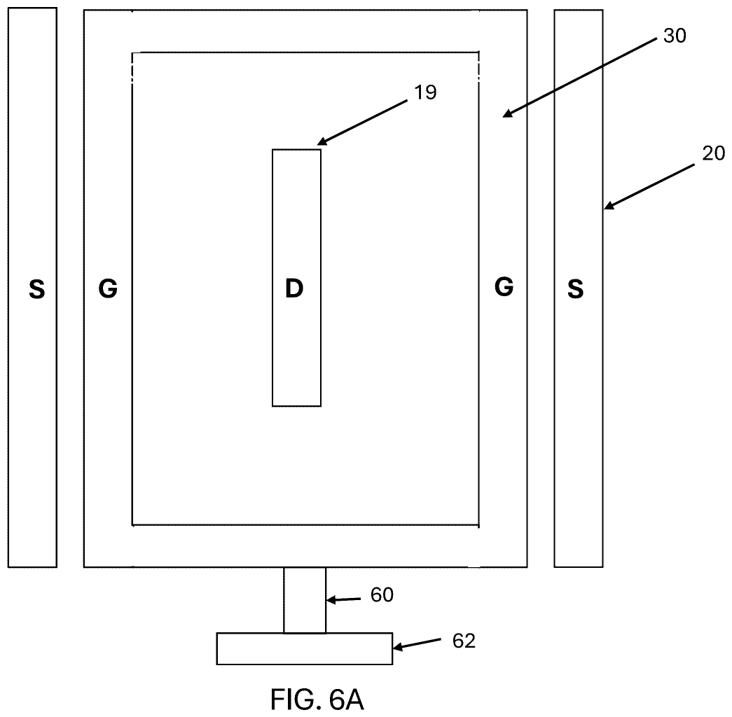

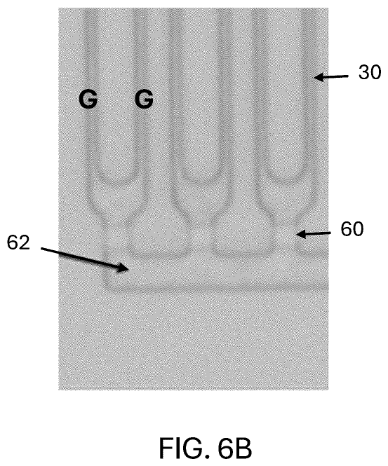

In FIGS. 4 and 5, the hole collector 23 is coupled at two opposite sides to respective gate metal contacts 30 by the GaN bridge 28, so that the GaN bridge and hole collector metal 32 is inside the gate racetrack. FIGS. 6A, 6B show an alternative layout in which the hole collector 23 is coupled at one side to a single annular gate 30. Here, the gate metal 30 forms a racetrack surrounding the drain contact 19. In this embodiment, the GaN bridge 60 extends from the GaN material below the gate metal 30, to the material beneath the hole collector metal 62. Thus, the entire bridge 60 and the metal 62 making contact to the GaN material, are disposed outside of the gate racetrack. The bridge 60 couples the hole collector GaN material and the hole collector metal 62 to the gate GaN material. The gate 30 racetrack forms a continuous closed loop, such as in the form of a square, circle, or rectangle, and the drain is positioned in the middle of the racetrack. In some embodiments, the hole collector 62 can be connected with multiple racetracks or gates 30 by one or more segments of bridge material 60.

FIG. 6B is top view picture showing an example of gate contact metal 30 and hole collector metal 62, and the GaN material between the two metals 30, 62. The GaN material forms a continuous network, and shows multiple racetrack gates 30 of FIG. 6A. As shown, the GaN material is only visible in the gap or bridge 60 between the gate metal 30 and the hole collector metal 62. The GaN material extends under the gate metal 30, the bridge 60, and the hole collector metal 62.

FIGS. 7A-7D show various possible connections of the hole collector metal 32 to the GaN material 25. FIG. 7A shows an embodiment in which the hole collector metal 32 is in direct contact only with the top surface of the GaN material 25. As shown in the cross-section view of FIG. 7B, in some embodiments the hole collector metal extends into a recess in the GaN material 25. As shown in the cross-section view of FIG. 7C, in some embodiments the hole collector metal 32 extends completely through the GaN material 25. FIG. 7D shows an embodiment in which a thin insulator 70, such as Si₃N₄, AlN or Al₂O₃, is disposed between the metal contacts 30, 32 and the GaN material layer 25. Thus, the insulator layer has a bottom surface that is formed over the top surface of the GaN layer 25, and the gate metal 30 and hole collector metal 32 each have a bottom surface that is formed over the top surface of the insulator. The thickness of the insulator 70 is from 0.1 nm to 3 nm. In this embodiment, the holes, which are mobile, tunnel from GaN material 25 through the insulator 70 to the hole collector metal 32. A fifth embodiment, not shown, is a combination of the embodiments of FIGS. 7B and 7D, in which the hole collector metal extends through insulator 70 into a recess in the GaN material 25.

As previously noted, FIGS. 12A, 12B illustrate the case where the GaN material is thinner, at least in part, in the gap between the gate contact metal and the hole collector metal. Referring to FIG. 12A, an embodiment is shown where the GaN material 115 is thinner in the bridge section 128, and the hole collector metal 132 is positioned in a recessed portion 135 of the GaN material 115. The thickness t1 may be in a range from 20 nm to 120 nm, and the thickness t2 may be the same as or less than thickness t1.

FIG. 12B shows another embodiment. A channel or groove 135 is formed in the section 34 between the gate metal 30 and the hole collector metal 32. Thus, the GaN material 125 is thinner in the region between the gate metal 130 and the hole collector metal 132. The thinned regions of FIGS. 12A, 12B can be provided, for example, when etching the TiN.

The hole collector metal 32, 132 is connected to a negative voltage. The negative voltage may be provided externally through an I/O terminal, or more preferably internally, through an integrated GaN circuit that generates a negative voltage. The negative voltage may also be provided by a silicon IC co-packaged with the GaN device. When the negative voltage is applied to the hole collector electrode 32, 62, holes in the GaN gate material are removed.

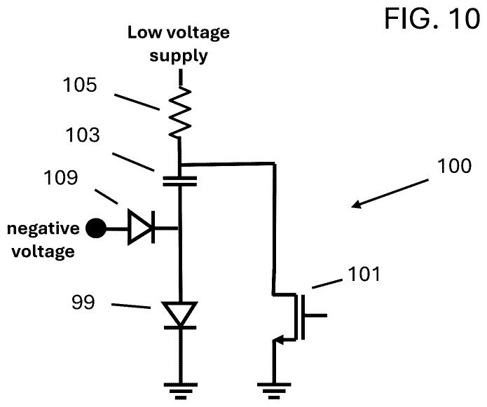

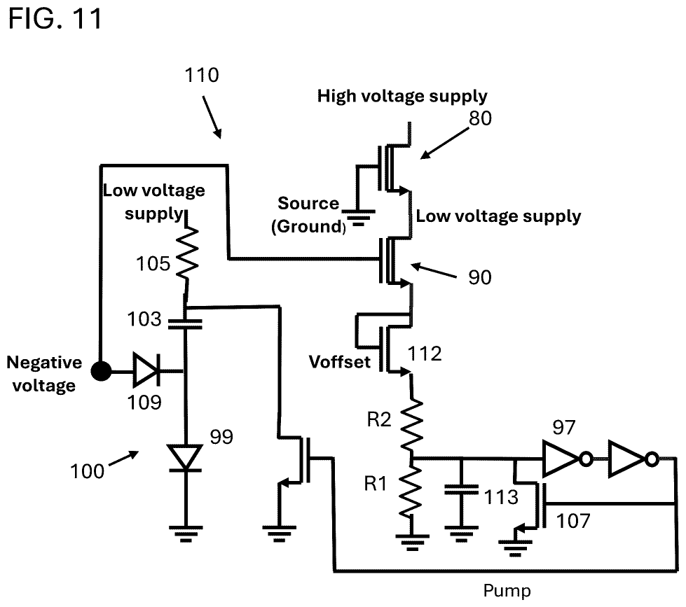

A preferred embodiment of an internal negative voltage generating circuit is shown in FIG. 11. The circuit is implemented entirely in GaN so that it can be integrated with the GaN transistor, and uses a charge pump (FIG. 10) to generate the negative voltage. The circuit generates a negative voltage in the range of −2V to −14V with an extremely low current consumption of less than 10 μA.

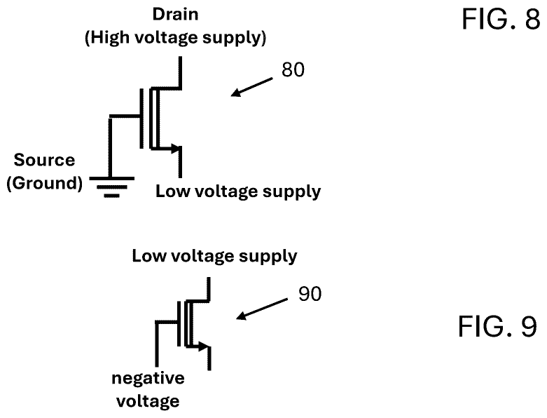

The internal voltage generating circuit uses a depletion mode GaN FET 80 as a linear supply. As shown in FIG. 8, an enhancement mode GaN FET is modified to a depletion mode GaN FET. By connecting the gate to ground and applying a voltage greater than the absolute value of the threshold voltage Vth on the drain of GaN FET 80, the source of GaN FET 80 will generate a supply voltage equal to approximately the absolute value of the threshold voltage of GaN FET 80, which is 14V for our particular depletion mode device design. This Vth can typically range from 1 to 20V. Thus, the source will generate a supply voltage of approximately −14V for our design.

In order to reduce the total current that the circuit can sink from the supply to 10 μA, circuitry is included to sense the negative voltage and activate the charge pump only when it is needed. As shown in FIG. 9, the sensor circuitry includes a depletion mode GaN FET 90 with its gate connected to the negative output of the voltage generating circuit of FIG. 9 (see FIG. 11).

GaN FET 90 of FIG. 9 acts as an up-level shifter. The voltage at the source of GaN FET 90 is equal to negative output of the voltage generating circuit plus the absolute value of the threshold voltage (approximately 14V). As explained below with respect to the complete circuit of FIG. 11, if the negative output of the voltage generating circuit plus 14V minus Voffset multiplied by the factor R1/(R1+R2) is greater than the threshold voltage of the inverter, then the charge pump (FIG. 10) is activated.

The operation of the charge pump circuit 100, shown in FIG. 10, is as follows. In steady state, the charge pump enhancement mode GaN FET 101 is OFF, the upper plate of the charge pump capacitor 103 is charged to the low voltage (LV) supply by resistor 105, and the lower plate of charge pump capacitor 100 is close to ground due to diode 99. The charge pump is activated by turning on GaN FET 101. Once GaN FET 101 is conducting, the upper plate of capacitor 103 is pulled down to ground and the lower plate of capacitor 103 is pulled below ground. At this point, diode 106 is turned on and the negative output of the voltage generating circuit is also pulled below ground. Diodes 99 and 109 in the circuit of FIG. 10 can be pn junction diodes, Schottky diodes or diode connected GaN FETs.

The operation of the sensing circuit is now described with reference to FIG. 11, which shows the complete negative voltage generating circuit 110. Depletion mode FET 80 generates the low voltage supply for the circuit. Depletion mode FET 90 senses the negative voltage generated by charge pump circuit 100. The source of FET 90 is approximately 14V higher compared to the gate. The source voltage can be lowered by a voltage offset (Voffset) via gate-to-drain connected FET 112 to reduce current consumption and charges a capacitor 113 through a voltage divider formed of resistors R1 and R2.

Once the voltage on capacitor 113

$$( negative voltage + \vert {V}_{T h}^{D e p} \vert - Voffset ) \frac{R 1}{R 1 + R 2}$$

reaches the threshold of inverter 97, the charge pump 100 is activated. The Pump signal triggers the charge pump circuit 100. The Pump signal also resets capacitor 113 through FET 107.

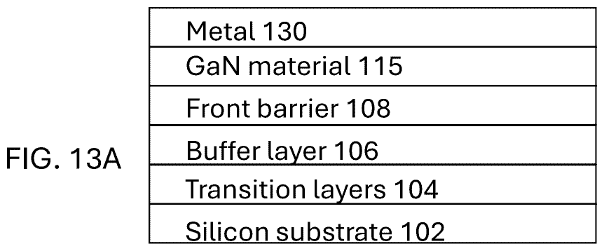

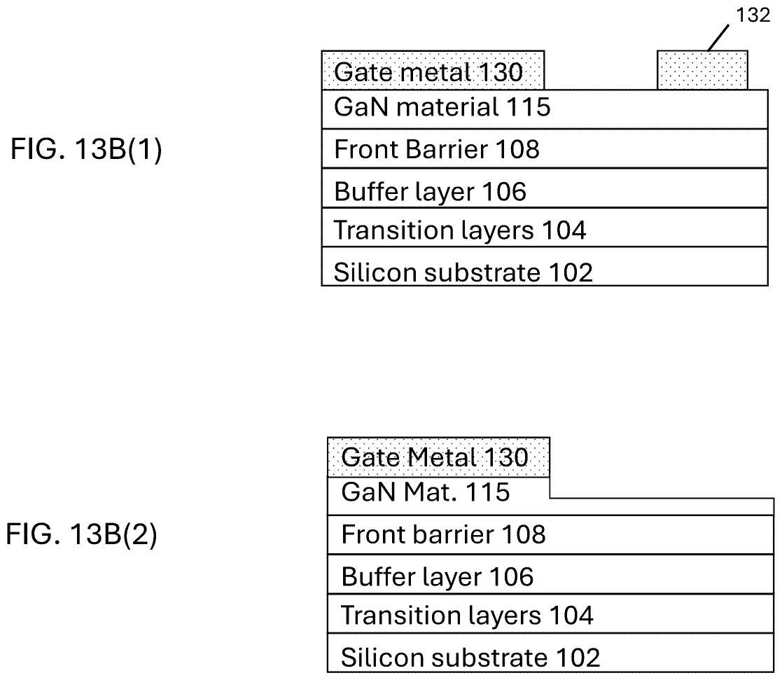

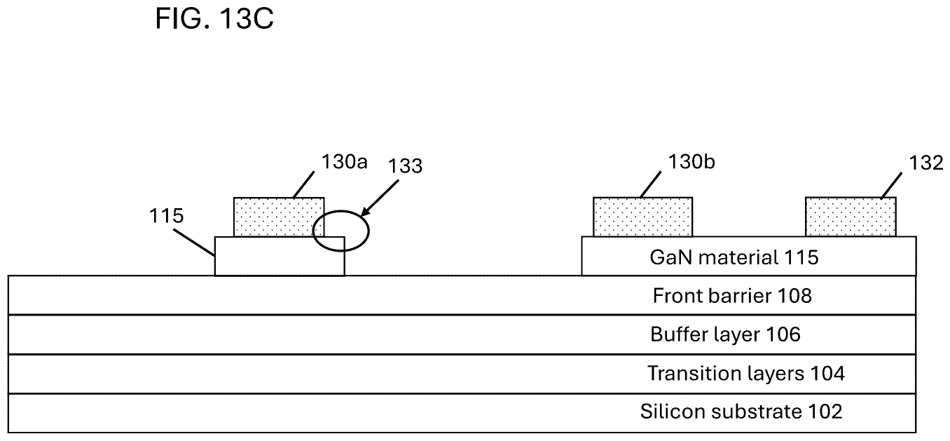

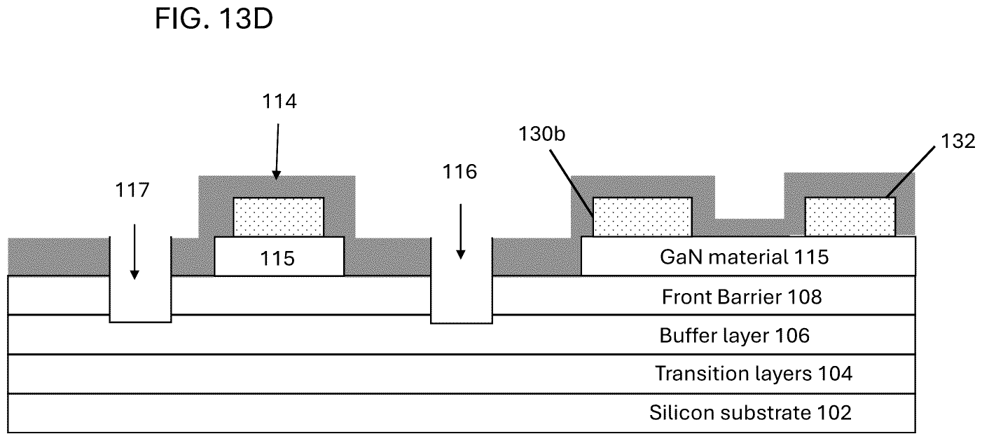

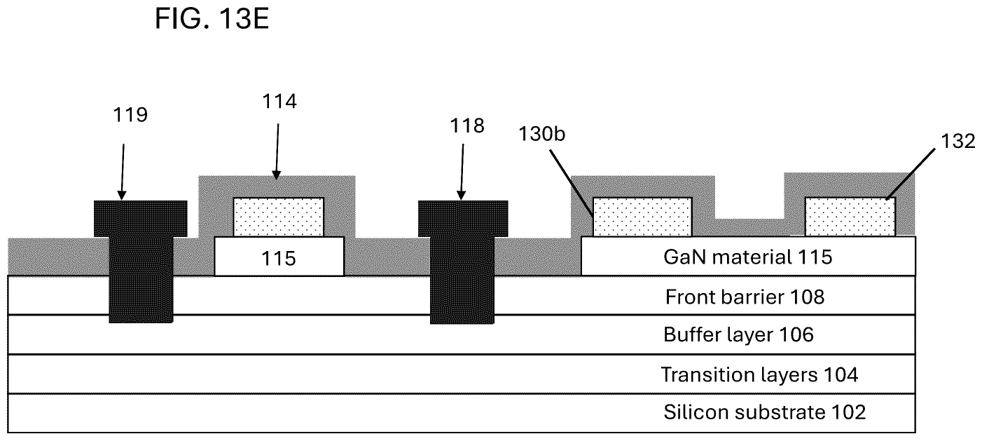

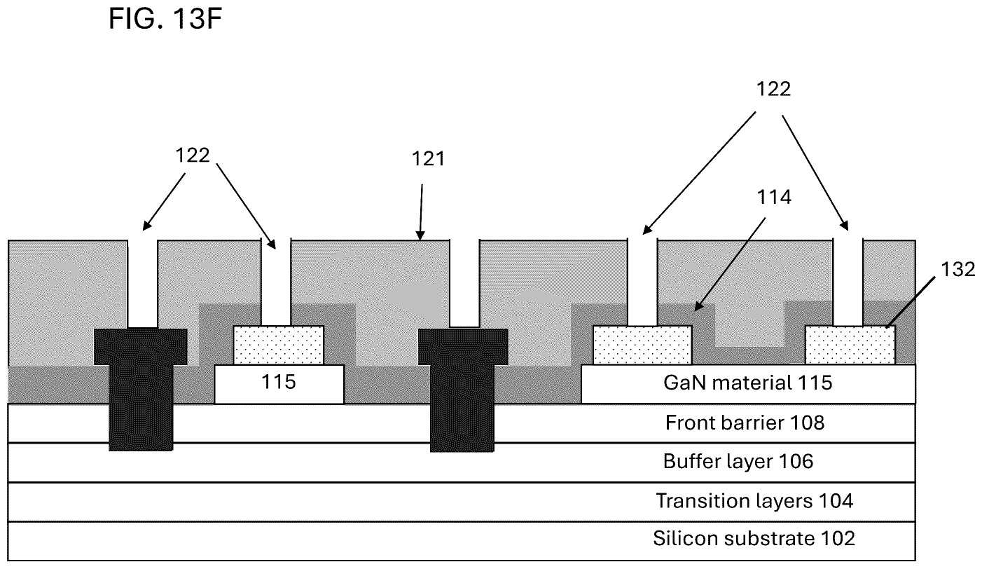

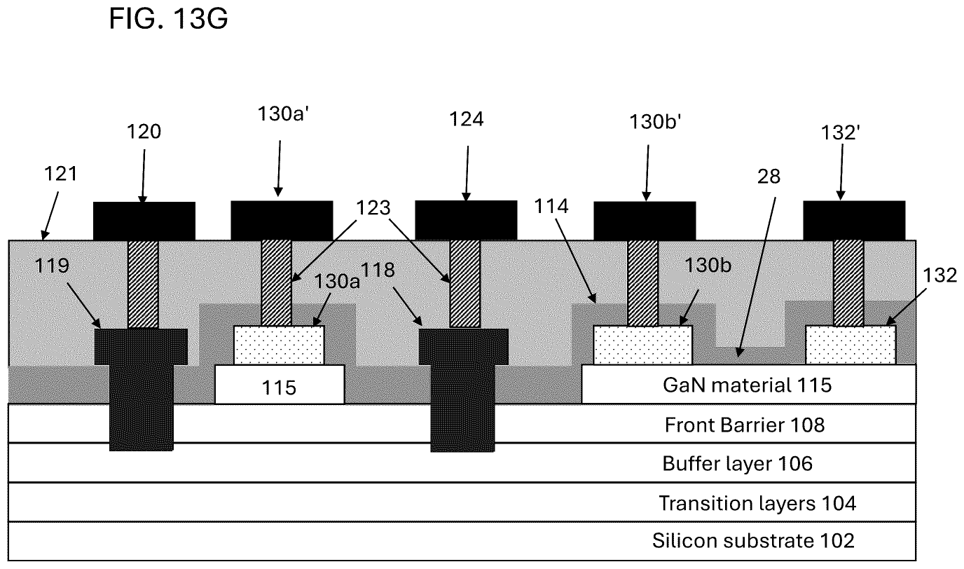

### Fabrication Process (FIGS. 13A-13G)

FIGS. 13A-13G illustrate a process of fabricating an enhancement mode GaN device in accordance with embodiments herein. Similar to conventional formation of enhancement-mode

GaN transistors, the description of the process begins from a structure (e.g., an epitaxial structure) that includes a silicon substrate 102, one or more transition layers 104 formed on the top surface of the substrate 102, a buffer layer 106 formed on the top surface of the transition layers 104, and an AlGaN front barrier layer 108 formed on the top surface of the buffer layer 106, for example, as disclosed in U.S. Pat. Nos. 8,890,168 and 10,622,455, the entire disclosures of which are incorporated herein by reference.

In accordance with embodiments herein, as shown in FIG. 13A, the front barrier 108 has a barrier top surface. A GaN material layer 115 is disposed (e.g., epitaxially disposed) on the barrier top surface of the barrier layer 108. The GaN material layer 115 has a GaN material top surface, and a deposition of a metal layer 130, such as titanium nitride (TiN) layer, is made on the GaN material top surface. The GaN material layer 115 may be 20 nm to 120 nm thick. The metal layer 130 may include TiN, Ti, Au, Cu, or other metals and metal combinations, and has a gate metal top surface.

From this structure, different options of etching the metal layer 130 are demonstrated in FIGS. 13B(1) and 13B(2) in accordance with embodiments herein. In FIG. 13B(1), the metal layer 130 is masked using a first mask and a portion of the metal layer 130 is etched to expose the GaN material layer 115 and form the gate metal contact 130 and the hole collector contact 132, while maintaining the GaN material layer 115. The hole collector contact 132 may be formed by the metal layer 130 or a second metal deposited on the GaN material layer 115. For example, the etched portion of the metal layer 130 may form a first portion of the metal layer 130 that forms the gate electrode 130b and a second portion of the metal layer 130 that forms the hole collector electrode 132 (FIG. 13C). Alternatively, the hole collector contact 132 may be formed by depositing a second metal on the GaN material layer 115 exposed by etching the portion of the metal layer 130. The second metal may be a different material than that of the gate metal contact 130b. The lateral spacing between the gate metal contact 130b and the hole collector electrode 132 may be 0.1 μm to 50 μm.

Optionally, in FIG. 13B(2), a portion of the metal layer 130 and the GaN material layer 115 is masked and etched in the formation of the hole collector contact. The etching of the portion of the GaN material 115 may be performed using the same etching process as the metal 130 or the portion of the GaN material 115 may be etched separately after the metal 130. The etching process removes the entire part of the etched gate metal layer 130 and a portion of the etched GaN layer 115, so that the remaining GaN layer 115 is thinner than the surrounding GaN material layer 115, as further shown in FIG. 12. Further, FIG. 13B(2) illustrates the avenue for using alternative metals and/or other configurations for the hole collection. For example, a different metal from the gate metal may be disposed to form the hole collection contact 132, and/or further metal/Schottky junctions may be incorporated to integrate control of the negative voltage supply for efficient hole collection.

Thus, in both of FIGS. 13(B)(1) and 13(B)(2), the GaN layer 115 is exposed, so that the gate metal 130 and hole collector metal 132 are electrically and separately structurally connected to the GaN material layer 115. Proceeding with the example in FIG. 13B(1) and referring to FIG. 13C, a portion of the metal layer 130 and the GaN material layer 115 is etched using a second mask to form the gate contacts 130a, 130b of the device. In some embodiments, the metal layer 130 may be further be partially wet-etched to form a self-aligned gate ledge 133 of the GaN material 115 from the gate metal 130a, as shown in FIG. 13C. Etching the at least one self-aligned gate ledge may be performed with a wet etch and may be performed by a process as described in U.S. Patent. No. 9,748,347, the entire disclosure of which is incorporated herein by reference.

In FIG. 13D, a first dielectric layer 114 is deposited over the device, including the portions of the gate metal layer 130, the hole collector metal 132, the GaN material layer 115, and the barrier layer 108. The dielectric layer 114 may be deposited using Low-Pressure Chemical Vapor Deposition (LPCVD). The dielectric 114 is preferably silicon nitride (Si₃N₄) with a thickness of ˜80 nm. The thickness of the dielectric layer 114 may vary from 20 nm to 200 nm in accordance with embodiments. The deposition of the dielectric 114 may further include annealing. For example, the ˜80 nm Si₃N₄ dielectric may be annealed at 850° C. The annealing temperature may vary from 750° C. to 950° C. for the Si₃N₄ dielectric.

After the deposition of the dielectric layer 114, a mask may be applied and portions of the dielectric layer 114 and the barrier layer 108 are etched to form a via 116 for the drain contact and a via 117 for the source contact through the front barrier 108 to or into the buffer layer 106.

In FIG. 13E, an ohmic metal is deposited into the vias 116 and 117 to form the drain first contact 118 and a first source contact 119, respectively, using a mask, further etching, and Rapid Thermal Annealing (RTA) at 550° C. The RTA temperature may be from 500° C. to 900° C. in accordance with embodiments.

In FIG. 13F, an Inter-Metal Dielectric (IMD) layer 121 is deposited over the device, namely over the top surfaces of the dielectric layer 114, drain contact 118, and source contact 119, as well as any exposed GaN material 115. The dielectric of the IMD 121 may be silicon dioxide (SiO₂). Following the IMD 121 deposition, the device is planarized to have a flat top surface. Contact vias 122 are etched through the IMD layer 121 to the drain contact 118 and the source contact 119 to form the source electrode 120, the drain electrode 124, the gate electrodes 130a, 130b and a hole collector electrode 132.

In FIG. 13G, a tungsten (W) plug 123 is disposed in each of the contact vias 122 from FIG. 13F. Then, routing metal is disposed on each of the W plugs 123 to form connections to the source electrode 120, the gate electrodes 130a and 130b, the drain electrode 124, and the hole collector electrode 132 of the device. The contact vias 122 couple the source electrode 120 to the source contact 119, the gate contacts 130a′, 130b′ to the gate metals 130a, 130b, the drain electrode 124 to the drain contact 118, and the hole collector contact 132′ to the hole collector metal 132, respectively.

As shown in the drawings and as described above, the present invention advantageously includes a hole collector which removes holes in the GaN gate material. As such, the GaN transistor of the present invention has lower gate leakage and a lower threshold voltage (Vth) shift. As further illustrated, the bottom surface of the hole collector metal 32 and the bottom surface of the gate metal 30 are each directly connected to the top surface of the GaN layer 25. And the GaN layer 25 is a single continuous layer. The source electrode 20, drain electrode 19, gate electrode 30, and hole collector electrode 32 are separate from each other. Accordingly, a negative voltage (with respect to the source) applied to the hole collector 32 removes holes from the GaN gate material section 31.

The above description and drawings are only to be considered illustrative of specific embodiments, which achieve the features and advantages described herein. Accordingly, the embodiments of the invention are not considered as being limited by the foregoing description and drawings.

More generally, even though the present disclosure and exemplary embodiments are described above with reference to the examples according to the accompanying drawings, it is to be understood that they are not restricted thereto. Rather, it is apparent to those skilled in the art that the disclosed embodiments can be modified in many ways without departing from the scope of the disclosure herein. Moreover, the terms and descriptions used herein are set forth by way of illustration only and are not meant as limitations. Those skilled in the art will recognize that many variations are possible within the spirit and scope of the disclosure as defined in the following claims, and their equivalents, in which all terms are to be understood in their broadest possible sense unless otherwise indicated.

1. An enhancement mode GaN transistor, comprising:
a source electrode, a gate electrode, a drain electrode, and a hole collector electrode, wherein the gate electrode and the hole collector electrode contact a GaN layer that serves as both GaN gate material under the gate electrode and as a connection from the GaN gate material layer to the hole collector electrode; and
wherein, when a negative voltage is applied to the hole collector electrode relative to the source electrode, holes in the GaN gate material are removed.

2. The enhancement mode GaN transistor of claim 1, wherein the GaN layer comprises AlₓGa_{y}In_{(1-x-y)}N.

3. The enhancement mode GaN transistor of claim 2, wherein the GaN layer further comprises a p-type dopant.

4. The enhancement mode GaN transistor of claim 3, wherein the GaN layer is compensated.

5. The enhancement mode GaN transistor of claim 1, wherein the GaN gate material comprises a stack of layers, the stack of layers comprising at least one GaN layer and at least one AlGaN layer.

6. The enhancement mode GaN transistor of claim 4, wherein the stack of layers further comprises indium.

7. The enhancement mode GaN transistor of claim 1, wherein the GaN layer has a recess between gate electrode and the hole collector electrode.

8. The enhancement mode GaN transistor of claim 1, wherein the hole collector electrode extends into the GaN gate material.

9. The enhancement mode GaN transistor of claim 1, wherein the hole collector electrode is electrically connected to an internal negative voltage power supply implemented in GaN.

10. The enhancement mode GaN transistor of claim 1, wherein the negative voltage is provided by a silicon IC co-packaged with the enhancement mode GaN transistor.

11. The enhancement mode transistor of claim 1, wherein the negative voltage is provided externally through an I/O terminal.

12. A method of manufacturing an enhancement mode transistor, the method comprising:
depositing a GaN layer onto a barrier layer of an epitaxial structure, the epitaxial structure comprising: a silicon substrate; one or more buffer layers disposed on the silicon substrate; a channel layer disposed on the one or more buffer layers; and the barrier layer disposed on the channel layer;
depositing a gate metal layer onto the GaN layer;
etching a first portion of the gate metal layer and forming a hole collection contact on the GaN layer;
etching a second portion of the gate metal layer and the GaN layer to form a gate contact;
depositing a first dielectric layer over the gate metal layer, the GaN layer, and the barrier layer;
forming a source contact and a drain contact through the first dielectric layer and the barrier layer to contact the channel layer;
depositing a second dielectric layer over the first dielectric layer, the source contact, and the drain contact;
forming a first connection to the hole collection contact to form a hole collector electrode, a second connection to the gate contact to form a gate electrode, a third connection to the source contact to form a source electrode, and a fourth connection to the drain contact to form a drain electrode.

13. The method of claim 12, wherein the hole collection contact is formed with a portion of the gate metal layer.

14. The method of claim 12, wherein the hole collection contact is formed by depositing a second metal on the GaN layer.

15. The method of claim 12, wherein etching the first portion of the gate metal layer comprises etching a portion of the GaN layer.
